(19) United States
(12) Patent Application Publication
(10) Pub. No.: US 2005/0106476 A1
(43) Pub. Date: May 19, 2005

(54) Method for producing a mask adapted to an exposure apparatus

(76) Inventors: Jens Hassmann, Dresden (DE); Johannes Kowalewski, Dresden (DE); Gerhard Kunkel, Radebeul (DE); Thorsten Schedel, Dresden (DE); Uwe Paul Schroder, Hopewell Junction, NY (US); Ina Voigt, Munchen (DE)

Correspondence Address: SLATER & MATSIL LLP, 17950 PRESTON ROAD, SUITE 1000, DALLAS, TX, 75252, US

(21) Appl. No.: 10/965,693

(22) Filed: Oct. 14, 2004

Related U.S. Application Data
(63) Continuation of application No. PCT/DE03/01280, filed on Apr. 16, 2003.

(30) Foreign Application Priority Data
Apr. 16, 2002 (DE) 102 16 820.2

(51) Int. Cl. G03F 9/00; G03C 5/00; G03B 27/54; G03F 1/08

(52) U.S. Cl. 430/5; 430/311; 430/30

(57) ABSTRACT

An item of information about the respective positions (501, 502, 601, 602) of at least two structure elements (50, 60) on a mask is provided. The displacement of the positional positions during the imaging by the lens system of the exposure apparatus, the displacement being governed by lens aberration, is measured and correction values (540, 640) are determined for each of the structure elements. Using the correction values (540, 640) the positions (501, 502, 601, 602) are changed in order to form new positions (505, 506, 605, 606) of the structure elements (50, 60) in such a way that the aberration effects can be compensated for. A mask (40) adapted to the exposure apparatus is exposed with the structures at the changed positions. The variation in the positional accuracies and the structure width distributions which is governed by the aberration of lenses is advantageously reduced.

This application is a continuation of co-pending International Application No. PCT/DE03/01280, filed Apr. 16, 2003, which designated the United States and was not published in English, and which is based on German Application No. 102 16 820.2 filed Apr. 16, 2002, both of which applications are incorporated herein by reference.

### TECHNICAL FIELD

The present invention relates to a method for producing a mask adapted to an exposure apparatus, which mask is suitable for exposing a wafer.

### BACKGROUND

In order to produce an integrated circuit, semiconductor wafers are provided with photosensitive resist layers in order to subsequently be exposed in an exposure apparatus with a structure, which corresponds to a structure plane of the integrated circuit. In subsequent etching steps, the exposed structure can be transferred from the resist layer into the underlying substrate of the wafer or layers deposited thereon. In the case of minimum achievable feature sizes of more than 140 nm, the exposure is carried out in the optical or UV wavelength range. So-called wafer steppers or scanners are used as exposure apparatuses. In these apparatuses, the structure of a previously produced mask is imaged onto the wafer by means of an optical lens system.

The limit of minimum achievable feature sizes continuously decreases with the development of new technologies. Associated with this, the extent of the tolerance ranges of deviations of actually measured values relative to the predetermined target values of the positional accuracy and structure width also decreases.

An essential cause of a variation in the deviations of the positional position and the structure widths, the deviations being measured by means of microscope apparatuses, is to be seen in lens faults manifested in so-called aberrations or distortions. In this case, the images of structures are represented in distorted fashion in the image plane. These imperfections are attributable for example to inaccuracies during lens grinding or depositions of layer material during processing in the exposure apparatus.

The lens aberrations, which occur during optical projection, can occur in a multiplicity of phenomena. A projection lens is usually characterized by the so-called aberration function of the light that passes through it. This function specifies the length by which the wave front of a light beam which passes through an arbitrary point of the lens at a distance from the center of the lens trails relative to a light beam which runs precisely through the center. In this case, the distortion phenomena that occur correspond to the different orders of the aberration function if the latter is developed for example in a set of orthonormal functions, the so-called Zernike polynomials.

Some of the aberration phenomena shall be presented below by way of example. So-called spherical aberration corresponds to those Zernike polynomials which are a quadratic or fourth-order function of the lens radius. In this case, the image contrast, the edge angle after etching and the dimensional accuracy of the structure transfer are possibly influenced in a disadvantageous manner.

Considered mathematically, this polynomial also corresponds to a deviation of the image distance set from an ideal focus value, this deviation also being referred to as defocus. Consequently, the disadvantageous effect of the distortion could be compensated for locally by changing the focus settings of the optical exposure system, but this could image other parts of the image field, which are set with an optimum focus, in an unsharp manner. A further problem is that the defocus in the case of spherical aberration is dependent on the size of the structure to be transferred.

Another type of distortion is brought about by so-called astigmatism. In this case, the defocusing acquires an angle-dependent component, so that the extent of the defocusing depends for example on the orientation of a line-gap structure in the X or Y direction.

Third-order Zernike polynomials correspond to so-called coma distortions. Different regions with a given radius of the projection lens make different contributions to the defocus, resulting in the possibility of the asymmetrical imaging in the image plane of originally symmetrical structures on the mask. In the production of memory products, for instance symmetrical trench capacitor pairs, this may lead to the unusability of the relevant trench capacitors owing to the respectively different imaging of the structures of the pair. Furthermore, the coma distortions lead to a displacement of the imaged structures in the image plane, the displacement being dependent on the feature size.

A further type of distortion is so-called three-leaf clover. The latter corresponds to a third-order Zernike polynomial with an angle-dependent component. Particularly in the case of phase masks, undesirable side effects such as, for instance, so-called side lobes, result with this type of distortion.

For the development of improved techniques for lens production, a particularly long lead time is required until suitable lenses are available for the next technology generation. It is therefore foreseeable that the variations in the structure widths and positional accuracies, which are brought about by lens faults occupy an increasing status in the instances of tolerances being exceeded. Aberration-governed deviations between measured and target values of 10-12 nm are established in memory products of the 140 nm technology generation. 3-σ tolerances for the structure width (critical dimension) are currently about 90 nm, and about 35 nm for the positional accuracy (overlay).

### SUMMARY OF THE INVENTION

Therefore, an object of the present invention is to provide a method for reducing the influence of the above-mentioned effects, in particular the lens aberrations, on the quality of the imaging of structures of masks on semiconductor wafers.

The object is achieved by means of a method for producing a mask adapted to an exposure apparatus, which mask is suitable for exposing a wafer, having the features described herein.

An assignment of a multiplicity of structure elements to their positional positions that are respectively to be reached on a wafer represents an item of information about a circuit arrangement to be formed on the wafer. In the semiconductor industry, such items of information are usually obtained by computer programs from specifications of functions to be fulfilled by the circuit arrangement. For the production of the individual mask planes, the items of information are converted into files, which reproduce the arrangement of the structures to be formed or of the structure elements, which construct the structures. By a mask writing apparatus, for instance, a laser or electron beam writing apparatus, or the computing installations connected with the latter, the files are converted into coordinates that can be implemented by the mask writing apparatus. In this case, for each point in the coordinate grid of the mask writing apparatus, it is ascertained whether or not the point is exposed by a laser or electron beam.

An assumption of the method according to the present invention is that the error when transferring the positions to be reached, proceeding from the information, which represents the assignment of the structure elements to the positional positions, to the mask is comparatively small. This relates, for instance, to the deflection of the laser or electron beam on account of changed ambient conditions.

According to the present invention, a correction in the assignments of the information, the correction being adapted to the respective structure, is in each case performed for each structure, which is to be imaged onto a wafer, in a manner dependent on its size, form and/or position and, in particular in a manner dependent on the lens used. The corrections may thus be different, in particular, for two adjacent structures. In this case, the correction comprises a compensation of the aberration error ascertained for the lens in the positional position of a structure element. If the aberration error is, by way of example, merely a displacement of the structure element in one direction, then a mask adapted thereto is produced for this exposure apparatus by displacing the corresponding structure by the same magnitude in a precisely opposite direction.

To that end, according to the present invention, first it is necessary to provide the information about a number of positions to be reached of structure elements on the mask. In the present document, the term structure elements denotes extracts from structures which characterize the form, size and orientation thereof, for example, corners, angles, characteristic rounded portions, individual points (grid points), etc. By way of example, a rectangle as structure is characterized by its four corner points as structure elements. According to the invention, these four corner points or structure elements can be corrected in terms of their positions in order to obtain the effect according to the invention.

According to the invention, the information with regard to the positions of the structure elements that are to be reached is compared with the positions of the structures that are imaged by the lens system.

In accordance with one refinement of the present invention, this can be achieved by the wafer being exposed by the exposure apparatus for example by means of a mask produced in accordance with the items of information provided, after which a determination of the absolute coordinate positions of the structure elements is carried out. These measured positions can be compared with the positions to be reached. The individually different aberration influences on the individual structures may also result in different changes in position of the individual structure elements.

Another possibility for the comparison of the positions to be reached with the imaged positions consists of carrying out a characterization of the lens not by an actual exposure by means of a mask, but rather by a direct measurement of the aberration properties of the lens, for example, by determination of the Zernike coefficients. Applying the aberration function determined to the provided information of the positions of the structure elements that are to be reached results in an imaging of the mask by the lens system into the image plane.

As a next step, on account of the comparison result, a correction value is individually calculated for each position to be reached. In accordance with one advantageous refinement of the present invention, the correction value corresponds to a displacement which is precisely opposite to the displacement—determined in the above-mentioned comparison—as a result of the lens distortion. This refinement is particularly advantageous in the case of a dimensionally accurate displacement of the entire structure, as may occur for instance as a result of a coma distortion.

Another possibility consists of area enlargements of the structures to be performed in a predetermined manner by means of the corrections of the positions to be reached. One example of this is the correction of the corresponding structure element in the formation of a so-called serif (OPC, Optical Proximity Correction) at an outer corner of a structure.

In a further step, the correction values are communicated to a mask writing apparatus. The mask writing apparatus encompasses the computing installations required for converting the original items of information. With the aid of these computing installations, the values of the positions of the structure elements that are to be reached are in each case changed, or calculated, by the determined correction values in order to form new positions of the structure elements that are to be reached. The fact that rules for example with regard to the minimum distance between two adjacent structures on the mask, etc. are to be complied with is preferably taken into account in this case.

With these changed items of information for the circuit layout, a mask is produced in the mask writing apparatus, which mask is precisely adapted to the lens system of the exposure apparatus and the specific circuit present.

Consequently, the locally different influence of the lens aberration can be compensated for in a particularly advantageous manner individually for each lens according to the present invention likewise locally by means of size, position or form adaptation of the structures. Focus deviations (defocus) within an exposure field (WFD, Intra-Field Focus Deviations) can thus likewise be corrected in the same way as higher-order lens faults.

### BRIEF DESCRIPTION OF THE DRAWINGS

The present invention will now be explained in more detail using exemplary embodiments with the aid of a drawing, in which:

FIG. 1, which includes FIGS. 1a and 1b, diagrammatically shows the effect, brought about by lens aberrations, of a displacing imaging of a pair of structures (a) and of an asymmetrical imaging (b);

FIG. 2, which includes FIGS. 2a and 2b, shows the step-by-step sequence for the production of the mask according to the invention; and

FIG. 3 shows an example according to the invention for the production of an adapted mask for memory modules by means of a wafer scanner.

### DETAILED DESCRIPTION OF ILLUSTRATIVE EMBODIMENTS

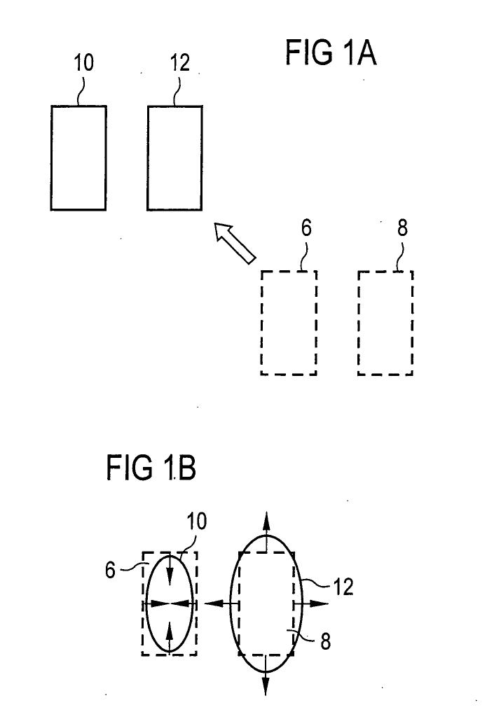

The effects of distortions that may be governed by the lens system of an exposure apparatus are outlined diagrammatically in FIG. 1. FIG. 1a shows, illustrated by dashed lines, a pair of structures 6, 8 for forming trench capacitor pairs for memory cells. As is represented by the arrow, the structures 6, 8 formed on the mask are imaged in a manner displaced by lens faults in terms of their position on structures 10, 12 on the wafer (solid lines). FIG. 1b shows a further effect, in which, although the same structures 6, 8 are not displaced in terms of their position, they are nonetheless imaged asymmetrically on the wafer in structures 10, 12, the left-hand structure in FIG. 1b being imaged in size-reduced fashion and the right-hand structure 12 being imaged in enlarged fashion. In this case, the four corners respectively present are displaced as structure elements inward (structure 10) and outward (structure 12).

Coma aberration is primarily responsible for the effects shown in FIGS. 1a and b.

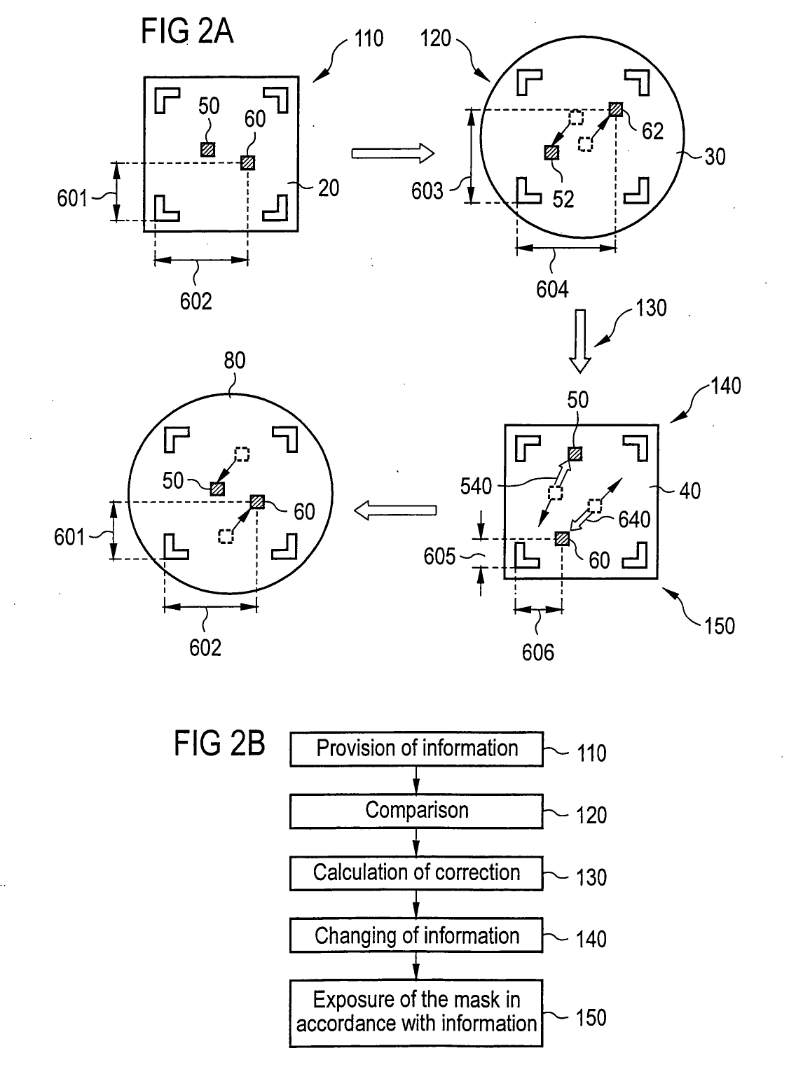

FIG. 2 diagrammatically shows the sequence of the method according to the invention using intermediate states of structures or structure elements at the positions to be reached and imaged positions on the wafer or the mask. FIG. 2a illustrates masks as rectangular and wafers in round form. No distinction is made between structures and structure elements in FIG. 2 for the sake of simplified illustration. The L-shaped marks in the corners of the masks and wafers designate absolute coordinate positions relative to which a position displacement can be ascertained. They need not actually be structured on the masks or wafers, but rather represent here diagrammatically the absolute system of coordinates ascertained by the relevant microscope measuring apparatus.

Firstly, provision is made of an item of information, which assigns a first X-Y position 501, 502 (not illustrated in FIG. 2) to a first structure element 50 and an X-Y position 601, 602 to a second structure element 60. In accordance with this information, a mask 20 is produced in a mask writing apparatus and communicated to an exposure apparatus with a lens system. The structure elements 50, 60 formed on the mask are imaged with their associated structures onto the wafer 30 by means of the lens system. As a result of the lens aberrations of the lens system, which have a locally different effect, the structure element 50 on the mask is imaged onto a structure element 52 on the wafer 30, while the structure element 60 on the mask 20 is imaged onto the structure element 62 on the wafer 30. The structure element 62 has imaged positions 603, 604 which are different from the positions 601, 602 to be reached.

Likewise, the imaged positions 503, 504 (not shown in FIG. 2) of the structure element 52 are different from the positions 501, 502 to be reached of the structure element 50 on the mask 20. The arrows in FIG. 2a (wafer 30 top right in the figure) in each case specify the direction of the displacement, which are different for each structure element 52, 62 on account of the intrinsic variation on account of the lens faults.

As the next step, for the structure element 60, 62, the X-Y positions 601, 602 to be reached are compared with the imaged X-Y position 603, 604. Individually different correction values 540, 640 for the respective structure elements 50 and 60 result from the comparison 120 under the specification that aberration-governed structure element displacements are to be compensated for by opposite displacement on the mask.

The mutually different correction values 540, 640 are communicated to the mask writing apparatus. Using associated computing installations, the correction values 540, 640 are applied in calculation to the positions 501, 502 and 601, 602, respectively, to be reached, so that the structure element 50 acquires from the information about the assignment of structure element to the positional position 501, 502 to be reached a new assignment to positional positions 505, 506 and the structure element 60 acquires a new assignment to positional positions 605, 606.

With the changed information, a mask 40 is then produced in the mask writing apparatus. The mask 40 is transferred precisely to that exposure apparatus for which the comparison 120 was made. The mask 40 is thus adapted to the lens system of the exposure apparatus. Using the adapted mask 40, a wafer 80 is exposed in the exposure apparatus, the position-corrected structure elements 50, 60 advantageously being obtained on the wafer on account of the lens distortions at the positions 501, 502 and 601, 602, respectively, which correspond to the first and second positions in the originally unchanged items of information. A high dimensional accuracy in the structure widths produced and a high positional accuracy are thus achieved.

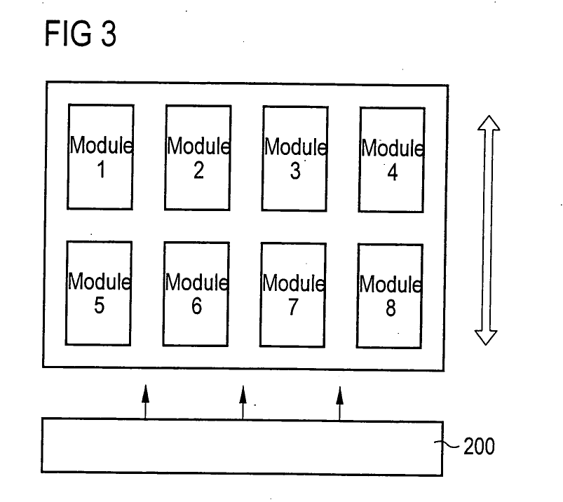

A further exemplary embodiment is shown in FIG. 3. In this case, the exposure field of a 140 nm DRAM module comprises eight 256 Mbit modules: module 1 to module 8. The latter each comprise a multiplicity of structures with structure elements. From the circuit layout, the information of the assignment of structures to positional positions is provided and a mask is produced. FIG. 3 shows the mask plane from which pairs of trench capacitor pairs are formed during the imaging onto the wafer. The characterization of the exposure apparatus used, a scanner in the present example, is carried out first of all. The extent to which the structures of the pairs on the wafer differ, which structures are of the same size on the mask in accordance with the information provided, is checked in this case. The corresponding measurement and the comparison are carried out column by column in each case for the areas of modules 1 and 5, modules 2 and 6, etc. Measurements carried out within the four regions are averaged in each case.

The individual 256 Mbit modules as illustrated are drawn with different correction values, also called biases, on a further mask, i.e., with a different size of the left-hand structure in relation to the right-hand structure, as is shown in FIG. 1b. In accordance with the four respectively different comparison results, for this purpose, four different correction values are also used for changing the information of the positional positions on which the drawing operation is based. It is thus possible to achieve a homogeneous distribution of the pairs of trench capacitor structures over the entire exposure field.

In the scanning direction of the scanning gap 200, which is represented by the arrows, modules 1 and 5 are provided with a first bias, modules 2 and 6 with a second bias, modules 3 and 7 with a third bias and modules 4 and 8 with a fourth bias during the changing 140 of the position information.

1. A method for producing a mask adapted to an exposure apparatus, the mask being suitable for exposing a wafer, the method comprising:
providing an item of information about at least one first position of at least one first structure element, and at least one second position of at least one second structure element on a test mask;
comparing each of the first and second positions with a respective position imaged on a wafer, which respective position is reached if the exposure apparatus carries out an exposure operation using the test mask for the imaging of the two structure elements;
calculating a first correction value of the first position and a second correction value of the second position in a manner dependent on the comparing;
ascertaining whether the first and the second correction value are calculated differently;
changing the values of the first and second positions in a manner dependent on this ascertaining, the changing being performed according to the following steps:
communicating at least the first and the second correction value to a mask writing apparatus;
changing the value of the first position to be reached by the first correction value in order to form a third position to be reached for the first structure element and changing the value of the second position to be reached by the second correction value in order to form a fourth position to be reached for the second structure element in the information; and
exposing the mask adapted to the exposure apparatus with the at least two structure elements in the mask writing apparatus in accordance with the information with the changed third and fourth positions.

2. The method as claimed in claim 1, wherein a magnitude and a direction of a difference between each of the first and second positions and the respective positions are determined during the comparing step;
the first correction value being equal in magnitude to a magnitude of a first difference and having a direction which is opposite to the direction of the first difference, the first difference by the difference between the first position and its respective position; and
the second correction value being equal in magnitude to a magnitude of a second difference and having a direction which is opposite to the direction of the second difference, the second difference by the difference between the second position and its respective position.

3. The method as claimed in claim 2, wherein the comparing step comprises:
exposing the test mask with the first and second structure elements in accordance with the information provided in a mask writing apparatus;
providing a further wafer in the exposure apparatus and transferring the test mask;
imaging the first and second structure elements of the test mask by the exposure apparatus in order to produce imaged first and second structure elements on the further wafer by means of the exposure apparatus;
determining the magnitude and the direction of the first difference; and
determining the magnitude and the direction of the second difference.

4. The method as claimed in claim 1, wherein the first and second structure elements in each case designate an area with a first transparency within surroundings with a second transparency, which is different from the first transparency, so that the area is displaced by means of the changing.

5. The method as claimed in claim 2, wherein the first and second structure elements in each case designate an area with a first transparency within surroundings with a second transparency, which is different from the first transparency, so that the area is displaced by means of the changing.

6. The method as claimed in claim 3, wherein the first and second structure elements in each case designate an area with a first transparency within surroundings with a second transparency, which is different from the first transparency, so that the area is displaced by means of the changing.

7. The method as claimed claim 1, wherein the first structure element comprises an edge extract or a corner of precisely a first area with a first transparency within surroundings with a second transparency, which is different from the first transparency, so that the changing of the first position to be reached influences the form and/or the size of the first area; and
the second structure element comprises an edge extract or a corner of precisely a second area with the first transparency within the surroundings with the second transparency, so that the changing of the second position to be reached influences the form and/or the size of the second area.

8. The method as claimed claim 2, wherein the first structure element comprises an edge extract or a corner of precisely a first area with a first transparency within surroundings with a second transparency, which is different from the first transparency, so that the changing of the first position to be reached influences the form and/or the size of the first area; and
the second structure element comprises an edge extract or a corner of precisely a second area with the first transparency within the surroundings with the second transparency, so that the changing of the second position to be reached influences the form and/or the size of the second area.

9. The method as claimed claim 9, wherein the first structure element comprises an edge extract or a corner of precisely a first area with a first transparency within surroundings with a second transparency, which is different from the first transparency, so that the changing of the first position to be reached influences the form and/or the size of the first area; and
the second structure element comprises an edge extract or a corner of precisely a second area with the first transparency within the surroundings with the second transparency, so that the changing of the second position to be reached influences the form and/or the size of the second area.

10. A method of manufacturing an integrated circuit, the method comprising:
producing a mask, the step of producing a mask comprising:
providing an item of information about at least one first position of at least one first structure element, and at least one second position of at least one second structure element on a test mask;
comparing each of the first and second positions with a respective position imaged on a wafer, which respective position is reached if the exposure apparatus carries out an exposure operation using the test mask for the imaging of the two structure elements;
calculating a first correction value of the first position and a second correction value of the second position in a manner dependent on the comparing;
ascertaining whether the first and the second correction value are calculated differently;
changing the values of the first and second positions in a manner dependent on this ascertaining, the changing being performed according to the following steps:
communicating at least the first and the second correction value to a mask writing apparatus;
changing the value of the first position to be reached by the first correction value in order to form a third position to be reached for the first structure element and changing the value of the second position to be reached by the second correction value in order to form a fourth position to be reached for the second structure element in the information; and
exposing the mask adapted to the exposure apparatus with the at least two structure elements in the mask writing apparatus in accordance with the information with the changed third and fourth positions;
providing a wafer with a photosensitive resist layer applied thereon;
disposing the wafer and the mask within an exposure apparatus;
exposing the photosensitive resist within the exposure apparatus to form a pattern in the photosensitive resist; and
transferring the pattern to the wafer.

11. The method as claimed in claim 10, wherein transferring the pattern to the wafer comprises etching a layer deposited over the wafer.

12. The method as claimed in claim 10, wherein a magnitude and a direction of a difference between each of the first and second positions and the respective positions are determined during the comparing step;
the first correction value being equal in magnitude to a magnitude of a first difference and having a direction which is opposite to the direction of the first difference, the first difference by the difference between the first position and its respective position; and
the second correction value being equal in magnitude to a magnitude of a second difference and having a direction which is opposite to the direction of the second difference, the second difference by the difference between the second position and its respective position.

13. The method as claimed in claim 12, wherein the comparing step comprises:
exposing the test mask with the first and second structure elements in accordance with the information provided in a mask writing apparatus;
providing a further wafer in the exposure apparatus and transferring the test mask;
imaging the first and second structure elements of the test mask by the exposure apparatus in order to produce imaged first and second structure elements on the further wafer by means of the exposure apparatus;
determining the magnitude and the direction of the first difference; and
determining the magnitude and the direction of the second difference.

14. The method as claimed in claim 10, wherein the first and second structure elements in each case designate an area with a first transparency within surroundings with a second transparency, which is different from the first transparency, so that the area is displaced by means of the changing.

15. The method as claimed claim 10, wherein the first structure element comprises an edge extract or a corner of precisely a first area with a first transparency within surroundings with a second transparency, which is different from the first transparency, so that the changing of the first position to be reached influences the form and/or the size of the first area; and
the second structure element comprises an edge extract or a corner of precisely a second area with the first transparency within the surroundings with the second transparency, so that the changing of the second position to be reached influences the form and/or the size of the second area.
